(19) United States
(12) Patent Application Publication
(10) Pub. No.: US 2026/0357415 A1
(43) Pub. Date: Nov. 12, 2026

(54) ELECTROSTATIC CHUCK, DEPOSITION APPARATUS INCLUDING THE SAME, AND ELECTRONIC DEVICE MANUFACTURED USING THE SAME

(71) Applicant: Samsung Display Co., Ltd., Yongin-si (KR)

(72) Inventors: SUNGJIN KIM, Yongin-si (KR); DONGKYUN KO, Yongin-si (KR); JAE BUM PAHK, Yongin-si (KR); JUN HA PARK, Yongin-si (KR); SUKWON JUNG, Yongin-si (KR)

(21) Appl. No.: 19/440,969

(22) Filed: Jan. 6, 2026

(30) Foreign Application Priority Data
May 12, 2025 (KR) 10-2025-0061138

(51) Int. Cl. C23C 14/50; C23C 14/04; H10K 71/16

(52) U.S. Cl. CPC C23C 14/50; C23C 14/042; H10K 71/166

(57) ABSTRACT

An electrostatic chuck includes: a dielectric layer comprising a central area and an edge area adjacent to the central area, wherein a first opening is formed in the dielectric layer in the central area; a charging layer under the dielectric layer, wherein a second opening connected to the first opening is formed in the charging layer in the central area; and a support structure under the charging layer, wherein a third opening connected to the second opening is formed in the support structure in the central area.

### CROSS - REFERENCE TO RELATED APPLICATION

The present application claims priority to and the benefit of Korean Patent Application No. 10-2025-0061138, filed on May 12, 2025, in the Korean Intellectual Property Office, the entire disclosure of which is incorporated herein by reference.

### BACKGROUND

### 1. Field

Aspects of some embodiments of the present disclosure relate generally to an electrostatic chuck, a deposition apparatus including the same, and an electronic device manufactured using the same.

### 2. Description of the Related Art

When forming an organic light-emitting element configuring an organic light-emitting display device (or electronic device), an organic layer may be formed by depositing a deposition material evaporated from an evaporation source of a deposition apparatus onto a substrate through a mask having a pixel pattern. In the deposition apparatus, the evaporation source may be installed at a lower portion of a chamber, the substrate is located at an upper portion of the chamber, and deposition may occur on a lower surface of the substrate. In this case, as the substrate size increases, the mask size may also increase, which may cause a central portion of the mask to sag during the deposition process, which may relatively reduce deposition precision.

The above information disclosed in this Background section is only for enhancement of understanding of the background and therefore the information discussed in this Background section does not necessarily constitute prior art.

### SUMMARY

Aspects of some embodiments of the present disclosure relate generally to an electrostatic chuck, a deposition apparatus including the same, and an electronic device manufactured using the same. For example, aspects of some embodiments of the present disclosure relate to an electrostatic chuck for adsorbing a deposition mask, a deposition apparatus including the same, and an electronic device manufactured using the same.

Aspects of some embodiments of the present disclosure include an electrostatic chuck for flatly adsorbing an object.

Aspects of some embodiments of the present disclosure include a deposition apparatus including the electrostatic chuck.

Aspects of some embodiments of the present disclosure include an electronic device manufactured using the electrostatic chuck.

An electrostatic chuck according to some embodiments of the present disclosure includes: a dielectric layer including a central area and an edge area adjacent to the central area, wherein a first opening is formed in the dielectric layer in the central area; a charging layer under the dielectric layer, wherein a second opening connected to the first opening is formed in the charging layer in the central area; and a support structure under the charging layer, wherein a third opening connected to the second opening is formed in the support structure in the central area.

According to some embodiments, the support structure may include: at least one upper insulating layer; at least one lower insulating layer under the at least one upper insulating layer; and a rigid member between the at least one upper insulating layer and the at least one lower insulating layer in a cross-section.

According to some embodiments, the at least one upper insulating layer and the at least one lower insulating layer may include a metal oxide.

According to some embodiments, the metal oxide may include aluminum oxide (Al₂O₃).

According to some embodiments, the rigid member may include a metal.

According to some embodiments, the metal may include titanium (Ti).

According to some embodiments, the first opening, the second opening, and the third opening may be arranged in a grid shape in a plan view.

A deposition apparatus according to some embodiments of the present disclosure includes: a deposition target substrate; a mask including a mask frame which faces the deposition target substrate and a mask sheet on the mask frame, wherein a plurality of deposition openings are formed in the mask sheet; and an electrostatic chuck facing the mask and including a central area and an edge area adjacent to the central area, wherein an opening corresponding to the plurality of deposition openings is formed in the electrostatic chuck in the central area.

According to some embodiments, the opening may penetrate the electrostatic chuck in a thickness direction.

According to some embodiments, the opening may overlap the plurality of deposition openings in a plan view.

According to some embodiments, the electrostatic chuck and the mask sheet may overlap each other in the central area.

According to some embodiments, when the mask is adsorbed on the electrostatic chuck, the electrostatic chuck and the mask may contact each other in the central area.

According to some embodiments, when the mask is adsorbed on the electrostatic chuck, the opening and the plurality of deposition openings may be connected to each other in the central area.

According to some embodiments, the electrostatic chuck may include: a dielectric layer on which the mask is loaded, wherein a first opening is formed in the dielectric layer in the central area; a charging layer under the dielectric layer, wherein a second opening is formed in the charging layer in the central area; and a support structure under the charging layer, wherein a third opening is formed in the support structure in the central area.

According to some embodiments, the first opening, the second opening, and the third opening may be connected to each other.

According to some embodiments, the support structure may include: at least one upper insulating layer; at least one lower insulating layer under the at least one upper insulating layer; and a rigid member between the at least one upper insulating layer and the at least one lower insulating layer in a cross-section.

According to some embodiments, the at least one upper insulating layer and the at least one lower insulating layer may include a metal oxide.

According to some embodiments, the rigid member may include a metal.

According to some embodiments, the opening may be arranged in a grid shape in a plan view.

An electronic device according to some embodiments of the present disclosure includes: a display module including at least one light-emitting element; and a power module configured to provide power to the display module. The display module is formed by a deposition process using a mask aligned by an electrostatic chuck. According to some embodiments, the electrostatic chuck includes: a dielectric layer including a central area and an edge area adjacent to the central area, wherein a first opening is formed in the dielectric layer in the central area; a charging layer under the dielectric layer, wherein a second opening connected to the first opening is formed in the charging layer in the central area; and a support structure under the charging layer, wherein a third opening connected to the second opening is formed in the support structure in the central area.

In an electrostatic chuck according to some embodiments of the present disclosure, an opening that penetrates a dielectric layer, a charging layer, and a support structure may be formed in a central area. Accordingly, an object loaded on the electrostatic chuck in the central area may be supported while maintaining a relatively flat surface. In addition, because the electrostatic chuck may include the support structure, the rigidity of the electrostatic chuck may be further relatively improved.

In a deposition apparatus according to some embodiments of the present disclosure, the deposition apparatus may include the electrostatic chuck and a mask loaded on the electrostatic chuck. Accordingly, because the mask is maintained flat during the deposition process, the deposition accuracy of a material deposited on a deposition target substrate may be relatively improved.

In an electronic device manufactured using the electrostatic chuck according to some embodiments of the present disclosure, the electronic device may be manufactured by the deposition process using the mask aligned by the electrostatic chuck. Accordingly, because the deposition accuracy of a material forming a light-emitting layer included in the electronic device is relatively improved, the light-emitting efficiency and the reliability of the electronic device may be further relatively improved.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an electrostatic chuck according to some embodiments of the present disclosure.

FIG. 2 is a cross-sectional view taken along the line I-I’ of FIG. 1.

FIG. 3 is an enlarged cross-sectional view illustrating the area A of FIG. 2.

FIG. 4 is a cross-sectional view illustrating a deposition apparatus including the electrostatic chuck of FIG. 1.

FIG. 5 is a plan view illustrating a mask frame of FIG. 4.

FIG. 6 is a plan view illustrating a mask sheet of FIG. 4.

FIG. 7 is a cross-sectional view illustrating an electrostatic chuck structure according to a comparative example to illustrate the effects of the present disclosure.

FIG. 8 is a block diagram illustrating an electronic device manufactured using the electrostatic chuck of FIG. 1.

FIG. 9 is a schematic view of the electronic device of FIG. 8 according to various embodiments.

FIG. 10 is a cross-sectional view illustrating a cross-section of a display module of FIG. 8.

### DETAILED DESCRIPTION

Hereinafter, aspects of some embodiments of the present disclosure will be described in more detail with reference to the accompanying drawings. The same reference numerals are used for the same components in the drawings, and redundant descriptions of the same components will be omitted.

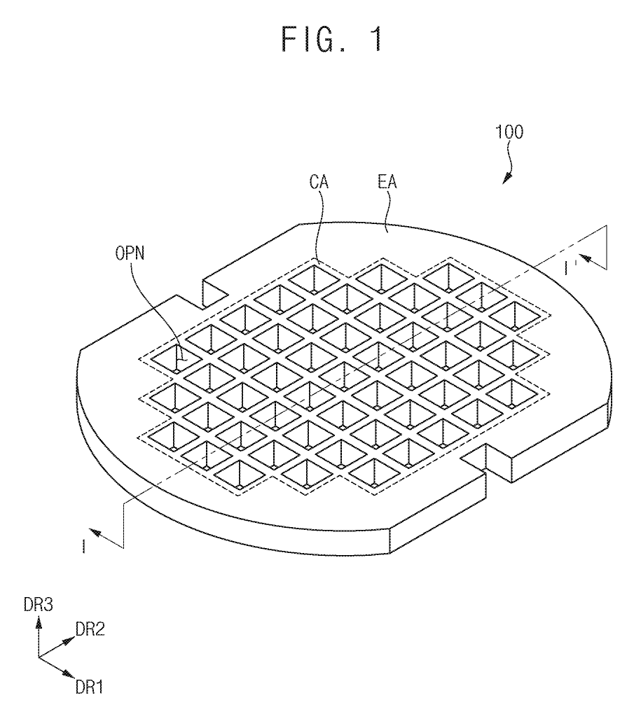

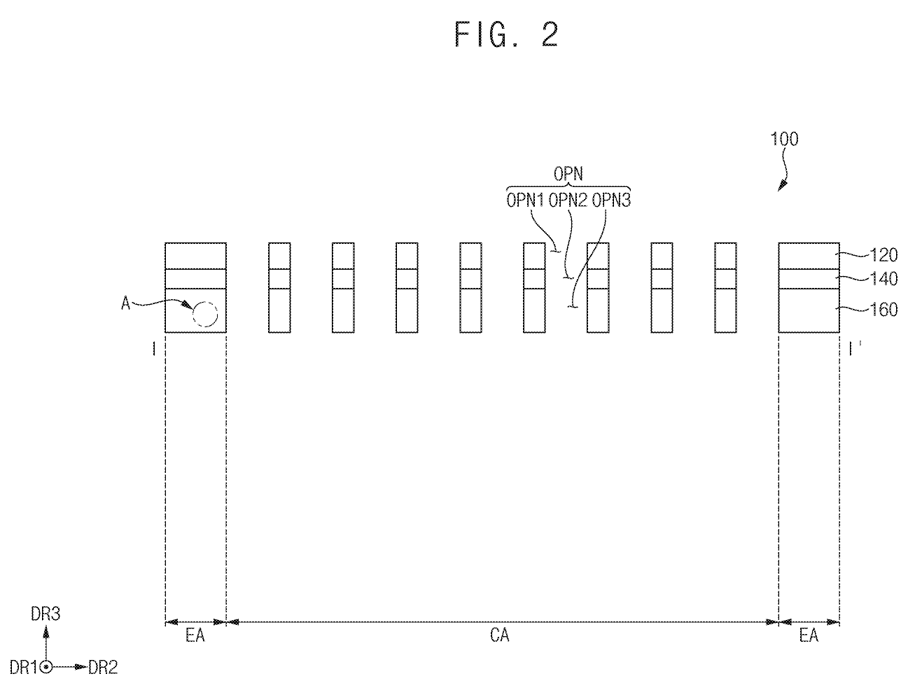

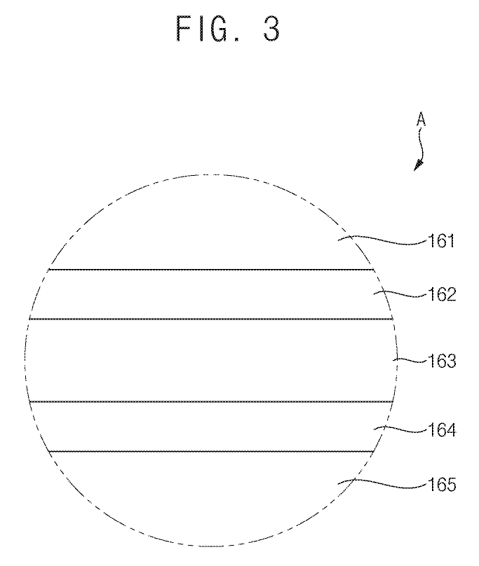

FIG. 1 is a perspective view illustrating an electrostatic chuck according to some embodiments of the present disclosure. FIG. 2 is a cross-sectional view taken along the line I-I’ of FIG. 1. FIG. 3 is an enlarged cross-sectional view illustrating the area A of FIG. 2.

In this specification, a plane may be defined by a first direction DR1 and a second direction DR2 intersecting the first direction DR1. For example, the first direction DR1 and the second direction DR2 may be perpendicular to each other. A direction normal to the plane, that is, a thickness direction of an electrostatic chuck 100 may be a third direction DR3. In other words, the third direction DR3 may be perpendicular to each of the first direction DR1 and the second direction DR2.

Referring to FIGS. 1, 2 and 3, the electrostatic chuck 100 according to some embodiments of the present disclosure may include a central area CA and an edge area EA. An opening OPN that penetrates the electrostatic chuck 100 in a thickness direction (e.g., the third direction DR3) may be formed in the central area CA. The edge area EA may be adjacent to the central area CA. For example, the edge area EA may be an area where the opening OPN is not formed (e.g., in a periphery of the opening OPN.

The electrostatic chuck 100 may include a dielectric layer 120, a charging layer 140, and a support structure 160. For example, the dielectric layer 120, the charging layer 140, and the support structure 160 may be sequentially stacked. The opening OPN may include a first opening OPN1, a second opening OPN2, and a third opening OPN3. The support structure 160 may include a first upper insulating layer 161, a second upper insulating layer 162, a rigid member 163, a first lower insulating layer 164, and a second lower insulating layer 165. For example, the first upper insulating layer 161, the second upper insulating layer 162, the rigid member 163, the first lower insulating layer 164, and the second lower insulating layer 165 may be sequentially stacked.

In this specification, the first upper insulating layer 161 and/or the second upper insulating layer 162 may be referred to as an upper insulating layer, and the first lower insulating layer 164 and/or the second lower insulating layer 165 may be referred to as a lower insulating layer.

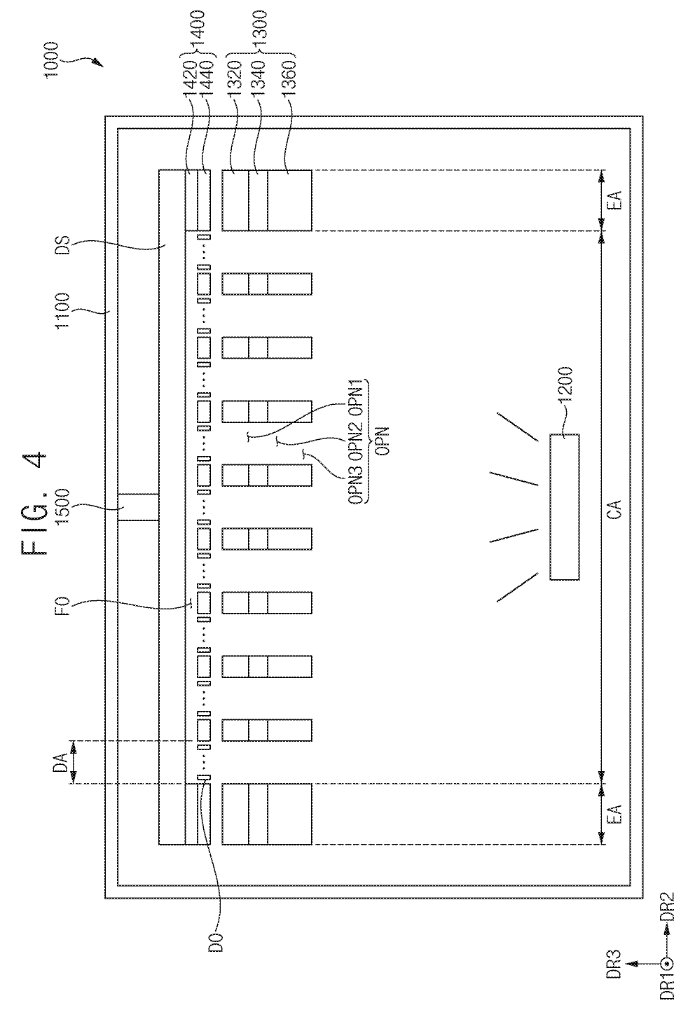

An adsorption object (e.g., a deposition target substrate DS of FIG. 4) may be loaded on the dielectric layer 120. For example, the deposition object may be loaded on the dielectric layer 120 by electrostatic force that interacts with the charged dielectric layer 120. According to some embodiments, the dielectric layer 120 may include an organic insulating material such as polyimide (PI).

The first opening OPN1 that penetrates the dielectric layer 120 in the thickness direction (e.g., the third direction DR3) may be formed in the dielectric layer 120 in the central area CA. According to some embodiments, in a plan view, the first opening OPN1 may extend along the first direction DR1. According to some embodiments, a plurality of first openings OPN1 may be arranged in the second direction DR2.

The charging layer 140 may be located under the dielectric layer 120. According to some embodiments, the charging layer 140 may include a conductive material. For example, the conductive material may include copper (Cu), aluminum (Al), gold (Au), silver (Ag), platinum (Pt), titanium (Ti), tungsten (W), molybdenum (Mo), a carbon nanotube (CNT), a conductive polymer, a transparent conductive oxide (TCO), and the like. These may be used alone or in combination with each other.

The charging layer 140 may include a first charging layer and a second charging layer spaced apart from the first charging layer in a plan view. A voltage applied to the first charging layer and a voltage applied to the second charging layer may have different levels. For example, when a positive voltage is applied to the first charging layer, a negative voltage may be applied to the second charging layer. For another example, when a negative voltage is applied to the first charging layer, a positive voltage may be applied to the second charging layer.

The second opening OPN2 that penetrates the charging layer 140 in the thickness direction (e.g., the third direction DR3) may be formed in the charging layer 140 in the central area CA. According to some embodiments, in a plan view, the second opening OPN2 may extend along the first direction DR1. According to some embodiments, a plurality of second opening OPN2 may be arranged in the second direction DR2.

The support structure 160 may be located under the charging layer 140. The support structure 160 may support the dielectric layer 120 and the charging layer 140. As the electrostatic chuck 100 includes the support structure 160, the durability of the electrostatic chuck 100 may be relatively improved.

The first upper insulating layer 161 may be located under the charging layer 140. The second upper insulating layer 162 may be located under the first upper insulating layer 161. The rigid member 163 may be located under the second upper insulating layer 162. The first lower insulating layer 164 may be located under the rigid member 163. The second lower insulating layer 165 may be located under the first lower insulating layer 164.

According to some embodiments, the first upper insulating layer 161, the second upper insulating layer 162, the first lower insulating layer 164, and the second lower insulating layer 165 may include a metal oxide. For example, the metal oxide may include titanium oxide (TiO₂), tantalum oxide (Ta₂O₅), hafnium oxide (HfO₂), zinc oxide (ZnO₂), aluminum oxide (Al₂O₃), and the like. These may be used alone or in combination with each other. However, the types of the metal oxide according to some embodiments of the present disclosure are not necessarily limited thereto.

According to some embodiments, the rigid member 163 may include molybdenum (Mo), nickel (Ni), titanium (Ti), and the like. These may be used alone or in combination with each other. However, the types of materials included in the rigid member 163 according to some embodiments of the present disclosure are not necessarily limited thereto.

According to some embodiments, the first upper insulating layer 161 and the second upper insulating layer 162 may be bonded to each other by being compressed after heating. According to some embodiments, the first lower insulating layer 164 and the second lower insulating layer 165 may be bonded to each other by being compressed after heating. According to some embodiments, the first upper insulating layer 161 and the second upper insulating layer 162, which are bonded to each other, may be bonded to an upper portion of the rigid member 163. In addition, the first lower insulating layer 164 and the second lower insulating layer 165, which are bonded to each other, may be bonded to a lower portion of the rigid member 163. Accordingly, the support structure 160 in which four insulating layers and the rigid member are stacked may be formed. However, the manufacturing order of the support structure 160 according to some embodiments of the present disclosure is not necessarily limited thereto.

The layered structure of the support structure 160 according to some embodiments of the present disclosure is not necessarily limited thereto. For example, the support structure 160 may have a structure in which one insulating layer or three or more insulating layers are stacked on the upper and/or lower portions of the rigid member.

The third opening OPN3 that penetrates the support structure 160 in the thickness direction (e.g., the third direction DR3) may be formed in the support structure 160 in the central area CA. For example, the third opening OPN3 may penetrate the first upper insulating layer 161, the second upper insulating layer 162, the rigid member 163, the first lower insulating layer 164, and the second lower insulating layer 165 in the thickness direction (e.g., the third direction DR3) in the central area CA. According to some embodiments, in a plan view, the third opening OPN3 may extend along the first direction DR1. According to some embodiments, a plurality of third openings OPN3 may be arranged in the second direction DR2.

According to some embodiments, the first opening OPN1, the second opening OPN2, and the third opening OPN3 may be connected to each other. In other words, the opening OPN may be an opening in which the first opening OPN1, the second opening OPN2, and the third opening OPN3 are connected to each other. According to some embodiments, a plurality of openings OPN may be arranged in the first direction DR1 and the second direction DR2. For example, the openings OPN may have a matrix or grid arrangement. For example, the first opening OPN1, the second opening OPN2, and the third opening OPN3 may together have a matrix or grid arrangement in a plan view.

As described above, in the electrostatic chuck 100 according to some embodiments of the present disclosure, the opening OPN that penetrates the dielectric layer 120, the charging layer 140, and the support structure 160 may be formed in the central area CA. Accordingly, an object loaded on the electrostatic chuck 100 in the central area CA may be supported while maintaining a flat surface. In addition, because the electrostatic chuck 100 includes the support structure 160, the rigidity of the electrostatic chuck 100 may be further relatively improved.

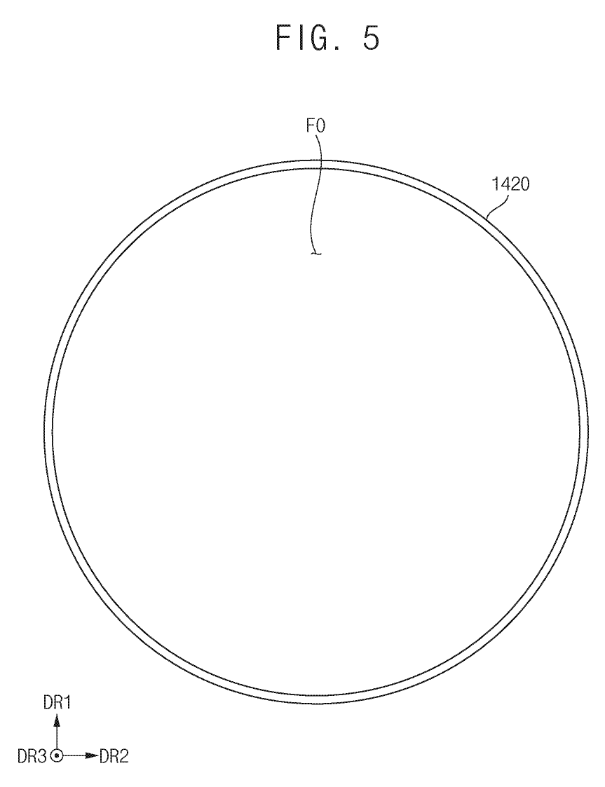

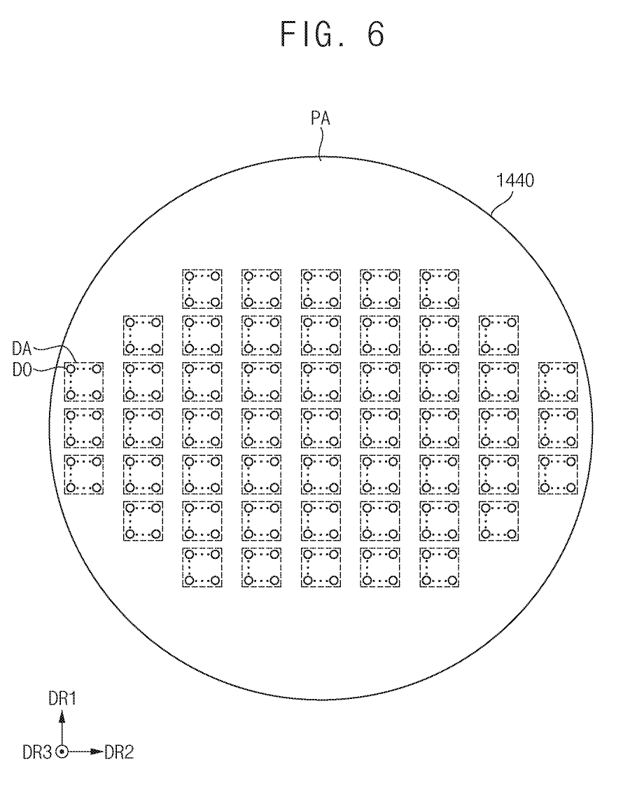

FIG. 4 is a cross-sectional view illustrating a deposition apparatus including the electrostatic chuck of FIG. 1. FIG. 5 is a plan view illustrating a mask frame of FIG. 4. FIG. 6 is a plan view illustrating a mask sheet of FIG. 4.

Hereinafter, redundant descriptions of the electrostatic chuck 100 described with reference to FIGS. 1-3 may be omitted or summarized.

Referring to FIGS. 4, 5, and 6, a deposition apparatus 1000 according to some embodiments of the present disclosure may include a deposition chamber 1100, a deposition source 1200, an electrostatic chuck 1300, a mask 1400, a support part 1500, and a deposition target substrate DS. The electrostatic chuck 1300 may include a dielectric layer 1320, a charging layer 1340, and a support structure 1360. The mask 1400 may include a mask frame 1420 and a mask sheet 1440.

The electrostatic chuck 1300 may correspond to the electrostatic chuck 100 of FIG. 1. The dielectric layer 1320 may correspond to the dielectric layer 120 of FIG. 2. The charging layer 1340 may correspond to the charging layer 140 of FIG. 2. The support structure 1360 may correspond to the support structure 160 of FIG. 2.

The deposition chamber 1100 may provide a space for performing a deposition process on a deposition target substrate DS. The deposition chamber 1100 may protect the deposition target substrate DS by providing a sealed environment from the outside. According to some embodiments, the deposition chamber 1100 may have a vacuum pressure (about 10 Torr to about 200 Torr) that is lower than the normal pressure (about 1 atm or about 760 Torr). However, the deposition chamber 1100 according to some embodiments of the present disclosure is not necessarily limited thereto.

The deposition source 1200 may include a deposition material. For example, the deposition material may be a sublimable or vaporizable material and may include at least one or an inorganic material and an organic material. The deposition material evaporated from the deposition source 1200 may pass through the mask 1400 and may be deposited on the deposition target substrate DS.

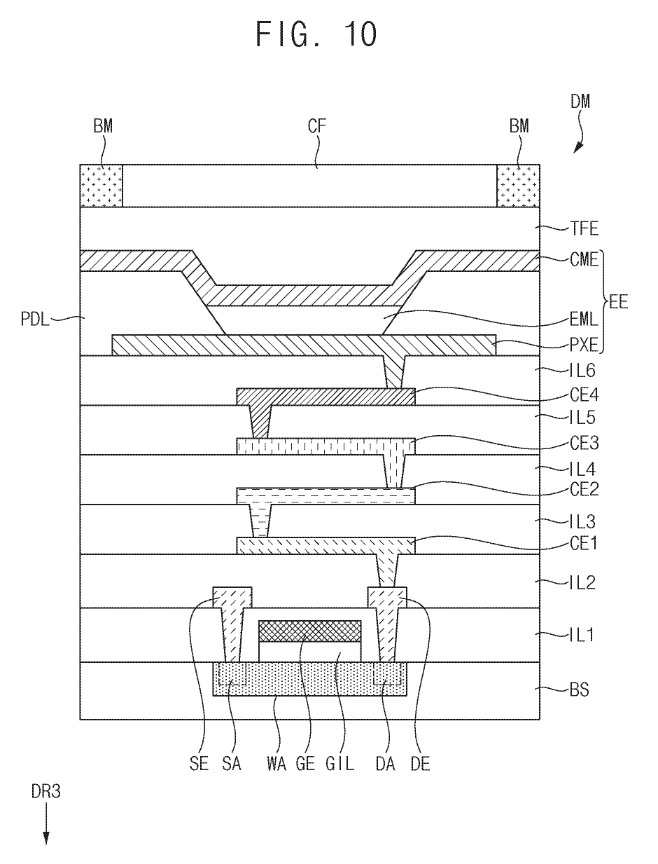

According to some embodiments, the mask 1400 may be a deposition mask. For example, the mask 1400 may be a mask for depositing a deposition material, such as an organic material, on a substrate. The organic material may be a material (e.g., an organic light-emitting material) that forms a light-emitting layer (e.g., a light-emitting layer EML of FIG. 10) that emits light.

According to some embodiments, the mask 1400 may be a mask for manufacturing a display device or electronic device including an ultra-small light-emitting element. For example, the mask 1400 may be a fine metal mask (FMM), a fine silicon mask (FSM), and the like. However, the types of the mask 1400 according to some embodiments of the present disclosure are not necessarily limited thereto, and the mask 1400 may be various types of masks used in a semiconductor process.

The mask frame 1420 may be a structure for supporting the mask sheet 1440. According to some embodiments, the mask frame 1420 may have a circular planar shape. According to some embodiments, the mask frame 1420 may have a polygonal or elliptical planar shape. According to some embodiments, the mask frame 1420 may include a silicon wafer. However, the shape of the mask frame 1420 and the material included in the mask frame 1420 according to some embodiments of the present disclosure are not necessarily limited thereto.

The mask sheet 1440 may be located on the mask frame 1420. The mask sheet 1440 may partially contact the mask frame 1420. According to some embodiments, the mask sheet 1440 may have a shape corresponding to the shape of the mask frame 1420. For example, the mask sheet 1440 may have a circular planar shape. For example, the mask sheet 1440 may have a polygonal or elliptical planar shape.

According to some embodiments, the mask sheet 1440 may include a conductive material, an inorganic material, and the like. For example, the conductive material may include titanium (Ti), titanium nitride (TiN), cobalt (Co), nickel (Ni), and the like. These may be used alone or in combination with each other. For example, the inorganic material may include silicon (Si), silicon nitride (SiNₓ), silicon oxide (SiOₓ), silicon oxynitride (SiOₓN_{y}), and the like. These may be used alone or in combination with each other. However, the shape of the mask sheet 1440 and the material included in the mask sheet 1440 according to some embodiments of the present disclosure are not necessarily limited thereto.

The mask sheet 1440 may include a deposition area DA and a peripheral area PA. For example, the deposition area DA may be adjacent to the peripheral area PA. A frame opening FO may be formed in the mask frame 1420. Deposition openings DO may be formed in the deposition area DA of the mask sheet 1440. According to some embodiments, in a plan view, the deposition openings DO may be positioned within the frame opening FO.

According to some embodiments, in the deposition chamber 1100, the position of the mask 1400 may be shifted on the electrostatic chuck 1300 may be shifted so that the position of the opening OPN corresponds to the position of the deposition openings DO.

According to some embodiments, in the center area CA, the mask sheet 1440 and the electrostatic chuck 1300 may overlap each other. For example, a portion of the mask sheet 1440 adjacent to the deposition area DA and a portion of the electrostatic chuck 1300 positioned in the center area CA may overlap each other in a plan view. According to some embodiments, when the mask sheet 1440 is adsorbed on the electrostatic chuck 1300, the mask sheet 1440 and the electrostatic chuck 1300 may contact each other in the center area CA. Accordingly, during the deposition process, the mask 1400 may be kept flat and fixed in position by being adsorbed on the electrostatic chuck 1300 in the center area CA.

According to some embodiments, the deposition openings DO may overlap the opening OPN in a plan view. According to some embodiments, when the mask 1400 is adsorbed on the electrostatic chuck 1300, the deposition openings DO may be connected to the opening OPN. For example, the deposition openings DO may be connected to the opening OPN to form a pathway for deposition materials evaporated or sprayed from the deposition source 1200.

The support part 1500 may fix or move the position of the deposition target substrate DS. For example, the support part 1500 may be fixed to an inner wall of the deposition chamber 1100. However, the role, the position, and the like of the support part 1500 according to some embodiments of the present disclosure are not necessarily limited thereto.

The deposition target substrate DS may be a substrate on which the deposition material is deposited. For example, the deposition target substrate DS may be a substrate forming the base of a display device or an electronic device on which a light-emitting layer, a metal layer, and the like are formed. According to some embodiments, the deposition target substrate DS may include silicon, a silicon wafer, glass, plastic, and the like. However, the types of the deposition target substrates DS according to some embodiments of the present disclosure are not necessarily limited thereto.

The deposition apparatus 1000 according to some embodiments of the present disclosure is not necessarily limited thereto, and a moving unit for moving the electrostatic chuck 1300 may be further located in the deposition chamber 1100.

In the deposition apparatus 1000 including the electrostatic chuck 1300 according to some embodiments of the present disclosure, the deposition apparatus 1000 may include the electrostatic chuck 1300 and the mask 1400 loaded on the electrostatic chuck 1300. Accordingly, because the mask 1400 is maintained flat while performing a deposition process, the deposition accuracy of a material deposited on the deposition target substrate DS may be relatively improved.

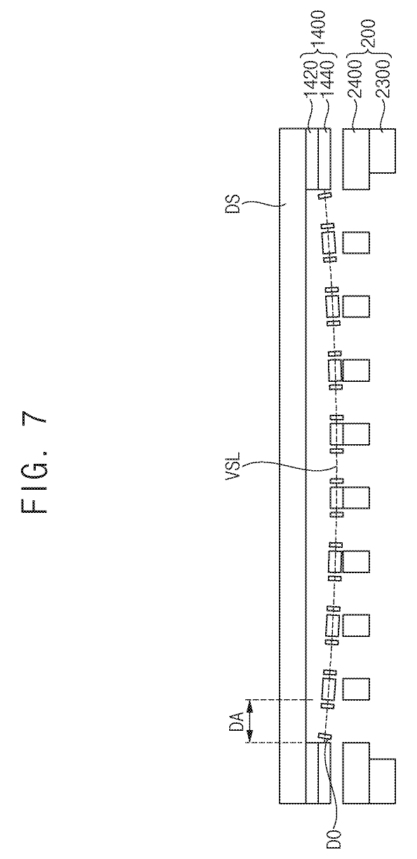

FIG. 7 is a cross-sectional view illustrating an electrostatic chuck structure according to a comparative example to illustrate the effects of the present disclosure.

Referring to FIG. 7, an electrostatic chuck structure 200 according to a comparative example may include an electrostatic chuck 2300 and a grid-like support part 2400. The electrostatic chuck 2300 may adsorb the mask 1400. While the mask 1400 is adsorbed, the grid-like support part 2400 may support a portion of the mask sheet 1420 around the deposition openings DO. An opening may be defined in the electrostatic chuck 2300, and the deposition openings DO may be positioned within the opening in a plan view. Accordingly, when the mask 1400 is adsorbed on the electrostatic chuck 2300, a portion of the mask sheet 1420 around the deposition openings DO may bend toward the electrostatic chuck 2300, and an imaginary slip line VSL may be defined. Accordingly, when the deposition process is performed using the electrostatic chuck structure 200 or the electrostatic chuck 2300 according to the comparative example, because the mask 1400 is not flat and a portion of the mask 1400 is bent, a deposition material may not be deposited at a target location on the deposition target substrate DS, and the deposition accuracy may be reduced.

Unlike the deposition process using the electrostatic chuck structure 200 or the electrostatic chuck 2300 according to the comparative example, the electrostatic chuck 1300 of FIG. 4 does not include a grid-like support part, and because the opening OPN having a grid-shape arrangement is formed in the central area CA of the electrostatic chuck 1300, the electrostatic chuck 1300 may be maintained flat during the deposition process, and the deposition accuracy may be further relatively improved.

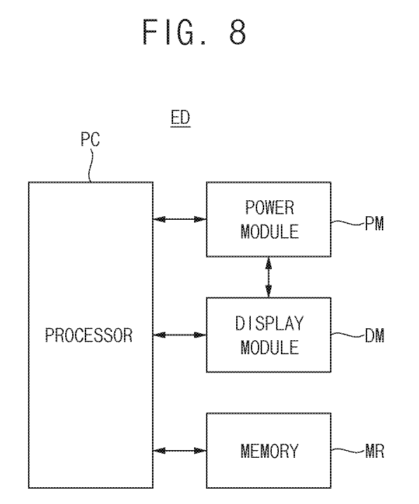

FIG. 8 is a block diagram illustrating an electronic device manufactured using the electrostatic chuck of FIG. 1.

Referring to FIG. 8, an electronic device ED according to some embodiments may include a display module DM, a processor PC, a memory MR, and a power module PM. The processor PC may include at least one of a central processing unit (CPU), an application processor (AP), a graphic processing unit (GPU), a communication processor (CP), an image signal processor (ISP), or a controller.

The memory MR may store data information required for operation of the processor PC or the display module DM. When the processor PC executes an application stored in the memory MR, an image data signal and/or an input control signal may be transmitted to the display module DM, and the display module DM may process the received signals and may output image information through a display screen.

The power module PM may include a power supply module, such as a power adapter or a battery device, etc., and a power conversion module that converts power supplied by the power supply module to generate the power required for operation of the electronic device ED. For example, the power module PM may provide power to the display module DM.

At least one of the components of the electronic device ED described above may be included in the display device according to the embodiments described above. In addition, some of the individual modules that are functionally included in one module may be included in the display device and others may be provided separately from the display device. For example, the display device may include the display module DM, and the processor PC, the memory MR, and the power module PM may be provided in the form of other devices in the electronic device ED other than the display device.

According to some embodiments, the electronic device ED may be manufactured using the electrostatic chuck 100 of FIG. 1 or the deposition apparatus 1000 of FIG. 4. For example, the display module DM may be manufactured by a deposition process using a mask aligned by the electrostatic chuck 100 of FIG. 1 or the deposition apparatus 1000 of FIG. 4. Accordingly, in the electronic device ED according to some embodiments of the present disclosure, because the deposition accuracy of a material forming a light-emitting layer (e.g., a light-emitting layer EML of FIG. 10) is relatively improved, the light-emitting efficiency and the reliability of the electronic device ED may be further relatively improved.

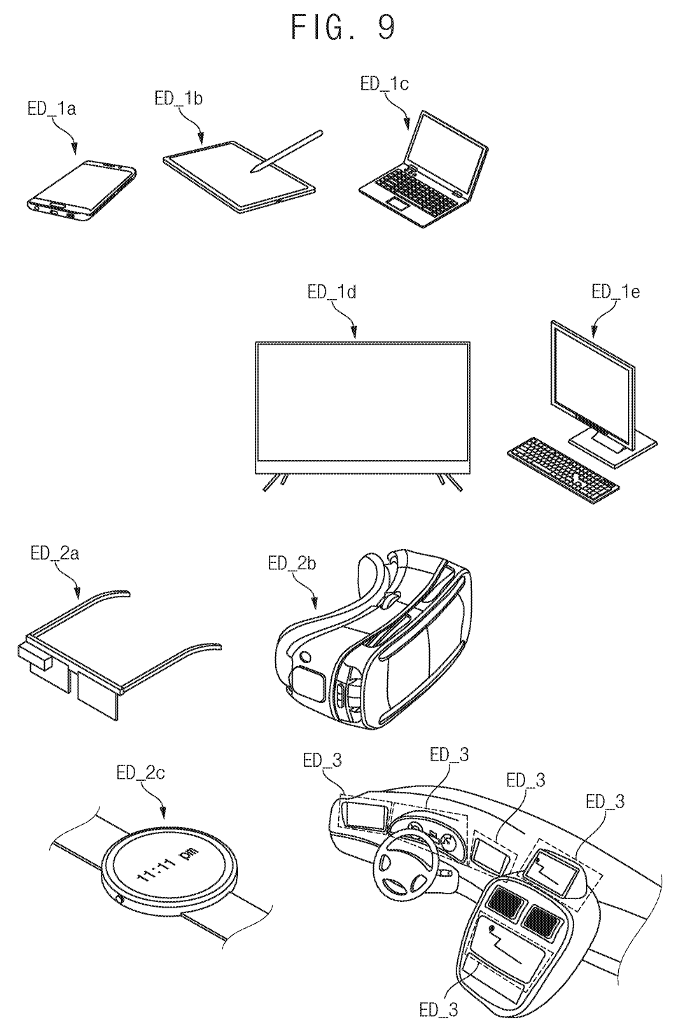

FIG. 9 is a schematic view of the electronic device of FIG. 8 according to various embodiments.

Referring to FIG. 9, various electronic devices ED according to some embodiments may include image display electronic devices such as a smartphones ED_1a, a tablet PC ED_1b, a laptop ED_1c, a television ED_1d, a desk monitor ED_1e, and the like, wearable electronic devices including display modules such as a smart glasses ED_2a, a head-mounted display ED_2b, and a smart watch ED_2c, and the like, and vehicle electronic devices ED_3 including display modules such as a CID (center information display) which may be located on an instrument panel, a center fascia, and a dashboard of an automobile and a room mirror display, or the like.

FIG. 10 is a cross-sectional view illustrating a cross-section of a display module of FIG. 8.

Referring to FIGS. 8, 9, and 10, the display module DM according to some embodiments may be applied to various electronic devices ED. The electronic device ED according to some embodiments may include the display module DM and may further include modules or devices having other additional functions in addition to the display module DM.

Referring to FIG. 10, the display module DM may include a base substrate BS, a gate insulating layer GIL, a gate electrode GE, a first insulating layer IL1, a source electrode SE, a drain electrode DE, a second insulating layer IL2, a first connection electrode CE1, a third insulating layer IL3, a second connection electrode CE2, a fourth insulating layer IL4, a third connection electrode CE3, a fifth insulating layer IL5, a fourth connection electrode CE4, a sixth insulating layer IL6, a pixel electrode PXE, a pixel defining layer PDL, a light-emitting layer EML, a common electrode CME, a thin film encapsulation layer TFE, a color filter CF, and a light blocking member BM.

The pixel electrode PXE, the light-emitting layer EML, and the common electrode CME may define a light-emitting element EE. A well area WA, a source area SA, and a drain area DA of the base substrate BS, the gate electrode GE, the source electrode SE, and the drain electrode DE may define a transistor.

The base substrate BS may serve as a base for the display module DM. According to some embodiments, the base substrate BS may include a silicon wafer. According to some embodiments, the base substrate BS may include the well area WA, the source area SA, and the drain area DA.

According to some embodiments, the well area WA may be adjacent to the source area SA and the drain area DA, and a channel area through which a charge carrier moves may be defined in the well area WA positioned between the source area SA and the drain area DA. The well area WA may be a p-well or an n-well. The p-well may refer to a substrate in which the charge carrier is a hole, and the n-well may refer to a substrate in which the charge carrier is an electron.

According to some embodiments, each of the source area SA and the drain area DA may be adjacent to an edge portion of the well area WA. According to some embodiments, each of the source area SA and the drain area DA may be an area doped with an n-type dopant or a p-type dopant. For example, when each of the source area SA and the drain area DA is doped with the p-type dopant, the well area WA may be n-well. For another example, when each of the source area SA and the drain area is doped with the n-type dopant, the well area WA may be p-well. However, the types of the well area WA and the types of the dopant doped in each of the source area SA and the drain area DA according to some embodiments of the present disclosure are examples and are not necessarily limited thereto.

However, the type of the base substrate BS according to some embodiments of the present disclosure is not necessarily limited thereto, and an active layer including the source area, the drain area, and the channel area may be further located on the base substrate BS. For example, the base substrate BS may be a transparent resin substrate such as polyimide. For example, the polyimide substrate may include a first organic layer, a first barrier layer, a second organic layer, and the like. For another example, the base substrate BS may include a quartz substrate (e.g., a synthetic quartz substrate, a fluorine-doped quartz substrate, and the like), a calcium fluoride substrate, a sodalime glass substrate, a non-alkali glass substrate, and the like. These may be used alone or in combination with each other.

The gate insulating layer GIL may be located on the base substrate BS. According to some embodiments, the gate insulating layer GIL may overlap at least a portion of the well area WA in a plan view. For example, the gate insulating layer GIL may overlap a central portion of the well area WA in a plan view, and the gate insulating layer GIL may not overlap an edge portion of the well area WA that is adjacent to each of the source area SA and the drain area DA in a plan view. According to some embodiments, the gate insulating layer GIL may not overlap each of the source area SA and the drain area DA in a plan view.

The gate electrode GE may be located on the gate insulating layer GIL. The gate electrode GE may overlap at least a portion of the well area WA in a plan view. For example, the gate electrode GE may overlap the central portion of the well area WA in a plan view, and the gate electrode GE may not overlap the edge portion of the well area WA adjacent to each of the source area SA and the drain area DA in a plan view. According to some embodiments, the gate electrodes GE may not overlap each of the source area SA and the drain area DA in a plan view. A portion of the well area WA overlapping the gate electrode GE may be defined as the channel area.

According to some embodiments, the gate electrode GE may include a conductive material. For example, the conductive material may include copper (Cu), titanium (Ti), aluminum (Al), molybdenum (Mo), and the like. These may be used alone or in combination with each other.

The first insulating layer IL1 may be located on the base substrate BS. For example, the first insulating layer IL1 may cover the gate electrode GE on the base substrate BS. According to some embodiments, the first insulating layer IL1 may cover the gate electrode GE and may provide a substantially flat upper surface. However, the first insulating layer IL1 according to some embodiments of the present disclosure is not necessarily limited thereto, and the first insulating layer IL1 may have a substantially uniform thickness along the profile of the gate electrode GE, and may create a step around the gate electrode GE. According to some embodiments, the first insulating layer IL1 may include an inorganic insulating material and/or an organic insulating material.

The source electrode SE and the drain electrode DE may be located on the first insulating layer IL1. The source electrode SE and the drain electrode DE may be electrically connected to portions of the base substrate BS positioned in the source area SA and the drain area DA, respectively. For example, the source electrode SE and the drain electrode DE may extend into the source area SA and the drain area DA, respectively, through contact holes that penetrate the first insulating layer IL1 in a thickness direction (e.g., the third direction DR3). According to some embodiments, each of the source electrode SE and the drain electrode DE may include a conductive material.

The second insulating layer IL2 may be located on the first insulating layer IL1. For example, the second insulating layer IL2 may cover the source electrode SE and the drain electrode DE on the first insulating layer IL1. According to some embodiments, the second insulating layer IL2 may cover the source electrode SE and the drain electrode DE and may provide a substantially flat upper surface. However, the second insulating layer IL2 according to some embodiments of the present disclosure is not necessarily limited thereto, and the second insulating layer IL2 may have a substantially uniform thickness along the profile of the source electrode SE and the drain electrode DE, and the second insulating layer IL2 may create a step around the source electrode SE and the drain electrode DE. According to some embodiments, the first insulating layer IL1 may include an inorganic insulating material and/or an organic insulating material.

The first connection electrode CE1 may be located on the second insulating layer IL2. According to some embodiments, the first connection electrode CE1 may contact the drain electrode DE through a contact hole that penetrates the second insulating layer IL2 in a thickness direction (e.g., the third direction DR3). However, the first connection electrode CE1 according to some embodiments of the present disclosure is not necessarily limited thereto, and the first connection electrode CE1 may contact the source electrode SE. According to some embodiments, the first connection electrode CE1 may include a conductive material.

The third insulating layer IL3 may be located on the first connection electrode CE1. For example, the third insulating layer IL3 may cover the first connection electrode CE1. According to some embodiments, the third insulating layer IL3 may include an inorganic insulating material and/or an organic insulating material.

The second connection electrode CE2 may be located on the third insulating layer IL3. According to some embodiments, the second connection electrode CE2 may contact the first connection electrode CE1 through a contact hole that penetrates the third insulating layer IL3 in a thickness direction (e.g., the third direction DR3). According to some embodiments, the second connection electrode CE2 may include a conductive material.

According to some embodiments, the second connection electrode CE2 may overlap the first connection electrode CE1 in a plan view. For example, the first connection electrode CE1 and the second connection electrode CE2 may form at least one capacitor. However, the first connection electrode CE1 and the second connection electrode CE2 according to some embodiments of the present disclosure are not necessarily limited thereto, and the first connection electrode CE1 and the second connection electrode CE2 may not overlap each other in a plan view.

The fourth insulating layer IL4 may be located on the second connection electrode CE2. For example, the fourth insulating layer IL4 may cover the second connection electrode CE2. According to some embodiments, the fourth insulating layer IL4 may include an inorganic insulating material and/or an organic insulating material.

The third connection electrode CE3 may be located on the fourth insulating layer IL4. According to some embodiments, the third connection electrode CE3 may contact the second connection electrode CE2 through a contact hole that penetrates the fourth insulating layer IL4 in a thickness direction (e.g., the third direction DR3). According to some embodiments, the third connection electrode CE3 may include a conductive material.

According to some embodiments, the third connection electrode CE3 may overlap the second connection electrode CE2 in a plan view. For example, the second connection electrode CE2 and the third connection electrode CE3 may form at least one capacitor. However, the second connection electrode CE2 and the third connection electrode CE3 according to some embodiments of the present disclosure are not necessarily limited thereto, and the second connection electrode CE2 and the third connection electrode CE3 may not overlap each other in a plan view.

The fifth insulating layer IL5 may be located on the third connection electrode CE3. For example, the fifth insulating layer IL5 may cover the third connection electrode CE3. According to some embodiments, the fifth insulating layer IL5 may include an inorganic insulating material and/or an organic insulating material.

The fourth connection electrode CE4 may be located on the fifth insulating layer IL5. According to some embodiments, the fourth connection electrode CE4 may contact the third connection electrode CE3 through a contact hole that penetrates the fifth insulating layer IL5 in a thickness direction (e.g., the third direction DR3). According to some embodiments, the fourth connection electrode CE4 may include a conductive material.

According to some embodiments, the fourth connection electrode CE4 may overlap the third connection electrode CE3 in a plan view. For example, the third connection electrode CE3 and the fourth connection electrode CE4 may form at least one capacitor. However, the third connection electrode CE3 and the fourth connection electrode CE4 according to some embodiments of the present disclosure are not necessarily limited thereto, and the third connection electrode CE3 and the fourth connection electrode CE4 may not overlap each other in a plan view.

The sixth insulating layer IL6 may be located on the fourth connection electrode CE4. For example, the sixth insulating layer IL6 may cover the fourth connection electrode CE4. According to some embodiments, the sixth insulating layer IL6 may include an inorganic insulating material and/or an organic insulating material.

The pixel electrode PXE may be located on the sixth insulating layer IL6. According to some embodiments, the pixel electrode PXE may be electrically connected to the fourth connection electrode CE4. For example, the pixel electrode PXE may contact the fourth connection electrode CE4 through a contact hole that penetrates the sixth insulating layer IL6 in a thickness direction (e.g., the third direction DR3).

According to some embodiments, the pixel electrode PXE may include a metal, an alloy, a conductive metal oxide, a conductive metal nitride, a transparent conductive material, and the like. For example, the pixel electrode PXE may include silver (Ag) and indium tin oxide (ITO). These may be used alone or in combination with each other.

The pixel defining layer PDL may be located on the sixth insulating layer IL6. According to some embodiments, the pixel defining layer PDL may partially cover the pixel electrode PXE. For example, the pixel defining layer PDL may define a hole exposing a central portion of the pixel electrode PXE, and the pixel defining layer PDL may cover an edge portion of the pixel electrode PXE. According to some embodiments, the pixel defining layer PDL may include an organic insulating material. According to some embodiments, the pixel defining layer PDL may further include a light blocking material.

The light-emitting layer EML may be located on the pixel electrode PXE. According to some embodiments, the light-emitting layer EML may be located in the hole of the pixel defining layer PDL. However, the light-emitting layer EML according to some embodiments of the present disclosure is not necessarily limited thereto, and the light-emitting layer EML may entirely cover the pixel defining layer PDL and the pixel electrode PXE.

According to some embodiments, the light-emitting layer EML may include an organic light-emitting material. The organic light-emitting material may include a low-molecular organic compound or a high-molecular organic compound. However, the present disclosure is not limited thereto, and the light-emitting layer EML may include a material such as a quantum dot.

The common electrode CME may be located on the pixel defining layer PDL. According to some embodiments, the common electrode CME may be located on the light-emitting layer EML. According to some embodiments, the common electrode CME may include a metal, an alloy, a conductive metal oxide, a conductive metal nitride, a transparent conductive material, and the like. For example, the common electrode CME may include aluminum (Al), platinum (Pt), silver (Ag), magnesium (Mg), gold (Au), chromium (Cr), tungsten (W), titanium (Ti), and the like. These may be used alone or in combination with each other.

The thin film encapsulation layer TFE may be located on the common electrode CME. According to some embodiments, the thin film encapsulation layer TFE may include an organic layer including an organic material and an inorganic layer including at least one inorganic material. For example, the thin-film encapsulation layer TFE may include a first inorganic layer, an organic layer, and a second inorganic layer that are stacked on the common electrode CME. The thin-film encapsulation layer TFE may seal an upper portion of the light-emitting element EE to protect the light-emitting element EE from external impurities.

The color filter CF may be located on the thin film encapsulation layer TFE. The color filter CF may transmit only light having a specific wavelength. For example, the color filter CF may include a first color filter that transmits light of a first color, a second color filter that transmits light of a second color, and a third color filter that transmits light of a third color. The first color filter, the second color filter, and the third color filter may be repeatedly arranged along the first direction DR1 and the second direction DR2.

The light blocking member BM may be located on the thin film encapsulation layer TFE. According to some embodiments, the light blocking member BM and the color filter CF may be repeatedly arranged along the first direction DR1 and the second direction DR2. For example, the light blocking member BM may be located between the first color filter and the second color filter in a plan view. The light blocking member BM may be located between the second color filter and the third color filter in a plan view. The light blocking member BM may be located between the first color filter and the third color filter in a plan view.

The light blocking member BM may prevent or reduce color mixing between adjacent color filters. According to some embodiments, the light blocking member BM may include a light blocking material. For example, the light blocking material may include carbon black, organic pigments, and the like.

However, the layered structure and the components included in the display module DM according to some embodiments of the present disclosure are not necessarily limited thereto. For example, the display module DM may include three or fewer connection electrodes stacked or five or more connection electrodes stacked, or may include five or fewer insulating layers stacked or seven or more insulating layers stacked. For example, the display module DM may further include a glass substrate located on the color filter CF, or may further include a sealing member and a filling member.

According to some embodiments, the base substrate BS may be the deposition target substrate DS of FIG. 4. According to some embodiments, the base substrate BS and one or more insulating layers stacked on the base substrate BS may be the deposition target substrate DS of FIG. 4. According to some embodiments, the deposition material included in the deposition source 1200 of FIG. 4 may be the same as the material included in the light-emitting layer EML.

According to some embodiments, the display module DM may be manufactured using the electrostatic chuck 100 of FIG. 1. According to some embodiments, the display module DM may be fabricated using the deposition apparatus 1000 of FIG. 4.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, and their equivalents.

What is claimed is:

1. An electrostatic chuck comprising:
a dielectric layer comprising a central area and an edge area adjacent to the central area, wherein a first opening is formed in the dielectric layer in the central area;
a charging layer under the dielectric layer, wherein a second opening connected to the first opening is formed in the charging layer in the central area; and
a support structure under the charging layer, wherein a third opening connected to the second opening is formed in the support structure in the central area.

2. The electrostatic chuck of claim 1, wherein the support structure comprises:
at least one upper insulating layer;
at least one lower insulating layer under the at least one upper insulating layer; and
a rigid member between the at least one upper insulating layer and the at least one lower insulating layer in a cross-section.

3. The electrostatic chuck of claim 2, wherein the at least one upper insulating layer and the at least one lower insulating layer comprise a metal oxide.

4. The electrostatic chuck of claim 3, wherein the metal oxide comprises aluminum oxide (Al₂O₃).

5. The electrostatic chuck of claim 2, wherein the rigid member comprises a metal.

6. The electrostatic chuck of claim 5, wherein the metal comprises titanium (Ti).

7. The electrostatic chuck of claim 1, wherein the first opening, the second opening, and the third opening are arranged in a grid shape in a plan view.

8. A deposition apparatus comprising:
a deposition target substrate;
a mask comprising a mask frame facing the deposition target substrate and a mask sheet on the mask frame, wherein a plurality of deposition openings are formed in the mask sheet; and
an electrostatic chuck facing the mask sheet and comprising a central area and an edge area adjacent to the central area, wherein an opening corresponding to the plurality of deposition openings is formed in the electrostatic chuck in the central area.

9. The deposition apparatus of claim 8, wherein the opening penetrates the electrostatic chuck in a thickness direction.

10. The deposition apparatus of claim 8, wherein the opening overlaps the plurality of deposition openings in a plan view.

11. The deposition apparatus of claim 8, wherein the electrostatic chuck and the mask sheet overlap each other in the central area.

12. The deposition apparatus of claim 11, wherein based on the mask being adsorbed on the electrostatic chuck, the electrostatic chuck and the mask are configured to contact each other in the central area.

13. The deposition apparatus of claim 11, wherein based on the mask being adsorbed on the electrostatic chuck, the opening and the plurality of deposition openings are configured to be connected to each other in the central area.

14. The deposition apparatus of claim 8, wherein the electrostatic chuck comprises:
a dielectric layer on which the mask is loaded, wherein a first opening is formed in the dielectric layer in the central area;
a charging layer under the dielectric layer, wherein a second opening is formed in the charging layer in the central area; and
a support structure under the charging layer, wherein a third opening is formed in the support structure in the central area.

15. The deposition apparatus of claim 14, wherein the first opening, the second opening, and the third opening are connected to each other.

16. The deposition apparatus of claim 14, wherein the support structure comprises:
at least one upper insulating layer;
at least one lower insulating layer under the at least one upper insulating layer; and
a rigid member between the at least one upper insulating layer and the at least one lower insulating layer in a cross-section.

17. The deposition apparatus of claim 16, wherein the at least one upper insulating layer and the at least one lower insulating layer comprise a metal oxide.

18. The deposition apparatus of claim 16, wherein the rigid member comprises a metal.

19. The deposition apparatus of claim 8, wherein the opening is arranged in a grid shape in a plan view.

20. An electronic device comprising:
a display module comprising at least one light-emitting element; and
a power module configured to provide power to the display module,
wherein the display module is formed by a deposition process using a mask aligned by an electrostatic chuck, and
wherein the electrostatic chuck comprises:
a dielectric layer comprising a central area and an edge area adjacent to the central area, wherein a first opening is formed in the dielectric layer in the central area;
a charging layer under the dielectric layer, wherein a second opening connected to the first opening is formed in the charging layer in the central area; and
a support structure under the charging layer, wherein a third opening connected to the second opening is formed in the support structure in the central area.
